(19) United States
(12) Patent Application Publication
(10) Pub. No.: US 2025/0389908 A1
(43) Pub. Date: Dec. 25, 2025

(54) Optical Receiver

(71) Applicant: Nippon Telegraph and Telephone Corporation, Tokyo (JP)

(72) Inventors: Shoko Tatsumi, Musashino-shi, Tokyo (JP); Masahiro Nada, Musashino-shi, Tokyo (JP); Yasuhiko Nakanishi, Musashino-shi, Tokyo (JP); Shigeru Kanazawa, Musashino-shi, Tokyo (JP)

(21) Appl. No.: 18/868,446

(22) PCT Filed: May 24, 2022
(86) PCT No.: PCT/JP2022/021183

§ 371 Date: Nov. 22, 2024

(51) Int. Cl. G02B 6/42; H10F 77/14

(52) U.S. Cl. CPC G02B 6/4214; G02B 6/4206; H10F 77/147

(57) ABSTRACT

Provided is an optical receiver which can be manufactured by a simple mounting method, and achieves both high sensitivity and miniaturization by extension of an optical path length. An optical receiver according to the present disclosure includes a planar light wave circuit which includes a spot size converter for converting a spot size of signal light incident from an optical fiber; a semiconductor substrate connected to the planar light wave circuit via a connecting surface; and a light-receiving element mounted on a substrate surface of the semiconductor substrate, in which the connecting surface is a facet surface that is in contact with the substrate surface at an acute angle or an obtuse angle so that the signal light emitted from the spot size converter is incident on a light-receiving surface of the full light-receiving element.

### TECHNICAL FIELD

The present disclosure relates to an optical receiver.

### BACKGROUND ART

With an increase in communication traffic in recent years, there is an increasing demand for higher speed and higher sensitivity for improving an amount of communication per time of an optical transceiver and, for miniaturization to accommodate the optical transceiver at a high density. As a typical example of a semiconductor light-receiving element used for optical communication, a photodiode is exemplified. The photodiode is an element that performs photoelectric exchange by generating electrons and holes under irradiation with light having an energy equal to or higher than the band gap of a semiconductor.

The most basic photodiode is a pin photodiode. A pin photodiode has a structure in which an i-layer with a low impurity density is sandwiched between p and n semiconductors doped with impurities at a high density on both sides. When a reverse bias is applied to a pin photodiode having such a structure, an electric field is generated in the i-layer, and electrons and holes generated by light irradiation are swept away and a photocurrent is generated. A ratio of the number of carriers that contribute to the photocurrent to the number of incident photons is called an external quantum efficiency, and it is essential to improve the external quantum efficiency for high sensitivity of the optical transceiver.

In order to improve the external quantum efficiency, it is effective to extend the optical path length in the light-absorbing layer of the light-receiving element. As a method for extending the optical path length in the light-receiving element, a method for increasing a thickness of the light-absorbing layer of the light-receiving element is known, but in this case, there is a problem that the high-speed response is hindered because a traveling time of the carrier increases.

As another method, a folded-back structure is formed so that the signal light passes through the light-absorbing layer of the light-receiving element a plurality of times. Further, in addition to such a folded-back structure, a method of extending the optical path length by making light incident obliquely on the light-receiving element is also known (see, for example, PTL 1).

On the other hand, as for an optical receiver using a semiconductor light-receiving element, a method of optically connecting the optical fiber and the light-receiving element through a two-lens system is known. However, in such a method of optically connecting the optical fiber via the lens, a space is required between the optical fiber and the light-receiving element in consideration of the thickness and focal length of the lens, and therefore, there is a problem that the entire element is increased in size. In order to reduce such a space, although a method of coupling the optical fiber and the light-receiving element by one lens instead of two lenses is also proposed, in this case, the accuracy of the distance between the optical fiber and the light-receiving element affects the optical coupling efficiency. Therefore, it is necessary to arrange the distance between fiber and the light-receiving element with high precision, which poses another problem that a mounting margin is extremely reduced. Although two lens systems are often used in optical systems of many optical receivers to secure the mounting margin at present, since a space of at least several millimeters is still required between the optical fiber and the light-receiving element, there still remains a problem in achieving the above-mentioned miniaturization.

### CITATION LIST

### Patent Literature

[PTL 1] Japanese Patent Application Publication No. 2011-187607

### SUMMARY OF INVENTION

The present disclosure has been made in view of the above-mentioned problems, and an object of the present disclosure is to provide an optical receiver which can be manufactured by a simple mounting method, and achieves both high sensitivity and miniaturization by extension of an optical path length in a light-absorbing layer of a light-receiving element.

In order to solve the above problem, the present disclosure discloses an optical receiver which includes: a planar light wave circuit which includes a spot size converter for converting a spot size of signal light incident from an optical fiber; a semiconductor substrate connected to the planar light wave circuit via a connecting surface; and a light-receiving element mounted on a substrate surface of the semiconductor substrate, in which the connecting surface is a facet surface that is in contact with the substrate surface at an acute angle or an obtuse angle so that the signal light emitted from the spot size converter is incident on a light-receiving surface of the full light-receiving element.

### BRIEF DESCRIPTION OF DRAWINGS

FIG. 1 is a diagram conceptually showing a structure of an optical receiver according to a first embodiment of the present disclosure. FIG. 1(a) shows a structure of an optical receiver 10a for refracting signal light to an upper surface side of a semiconductor substrate 13 on a facet surface, and FIG. 1(b) shows a structure of an optical receiver 10b having a folded-back structure which reflects the signal light at the bottom surface of the semiconductor substrate 13, after refracting the signal light toward the bottom surface of the semiconductor substrate 13 at the facet surface.

FIG. 2 is a diagram showing an example of a spot size converter 12.

FIG. 3 is a diagram conceptually showing an implementation example of an optical receiver according to the present disclosure.

FIG. 4 is a diagram conceptually showing a structure of an optical receiver according to a second embodiment of the present disclosure, FIG. 4(a) shows an optical receiver 30a for refracting signal light to the upper surface side of a semiconductor substrate 13 on a facet surface, and FIG. 4(b) shows an optical receiver 30b having a folded-back structure which reflects the signal light at the bottom surface of the semiconductor substrate 13, after refracting the signal light toward the bottom surface of the semiconductor substrate 13 at the facet surface.

FIG. 5 is a diagram conceptually showing a structure of an optical receiver 40 according to a third embodiment of the present disclosure, FIG. 5(a) is a top view and FIG. 5(b) is a side view.

FIG. 6 is a diagram conceptually showing a structure of an optical receiver 50 according to a fifth embodiment of the present disclosure.

### DESCRIPTION OF EMBODIMENTS

Various embodiments of the present disclosure will now be described in detail with reference to the accompanying drawings. The same or similar reference numerals indicate the same or similar elements and repeated description thereof may be omitted. Materials and numerical values are intended for illustration and are not intended to limit the technical scope of the present disclosure. The following description is an example, and some configurations may be omitted or modified, or may be implemented with additional configurations, unless it departs from the gist of one embodiment of the present disclosure.

An optical receiver according to the present disclosure is configured such that signal light guided from an optical fiber propagates inside a substrate via a planar light wave circuit and is input to a light-receiving element installed on the substrate, and a connecting surface between a parallel light wave circuit and the substrate is a surface having an inclination with respect to a traveling direction of the signal light. Since the signal light is obliquely input to the light-receiving element by refracting the signal light on the connecting surface having the inclination, an optical path length in the light-absorbing layer of the light-receiving element is extended, and the sensitivity of the optical receiver is improved. Hereinafter, in the present specification, the connecting surface having the inclination is referred to as a “facet surface”. Since the optical receiver includes the facet surface, high sensitivity of the optical receiver can be realized without installing a lens system as in the related art, and hence high sensitivity and miniaturization can be achieved. Further, the optical receiver having the facet surface can be easily manufactured by an existing mounting method as described later.

### First Embodiment

A first embodiment of the present disclosure will now be described in detail with reference to the accompanying drawings. The optical receiver according to the present embodiment is formed such that signal light to be input to the light-receiving element propagates inside the substrate, and the signal light input to the substrate is refracted by the facet surface, thereby obliquely entering the light-receiving element.

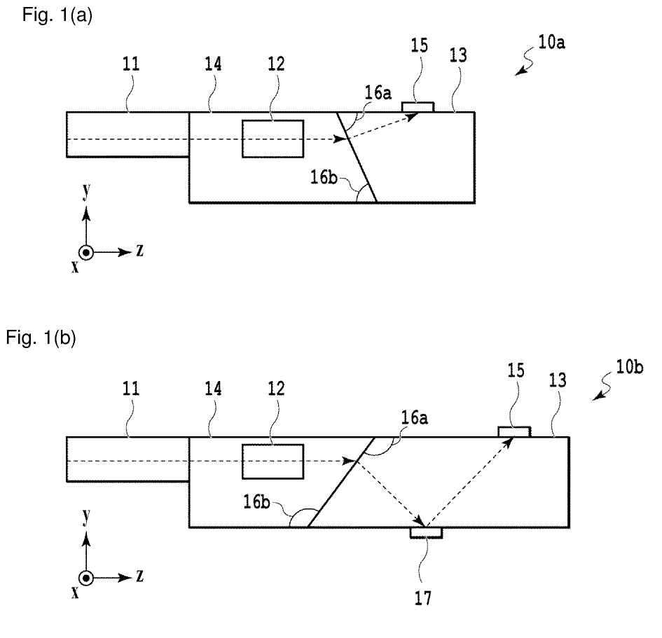

FIG. 1 is a diagram conceptually showing a structure of an optical receiver according to a first embodiment of the present disclosure. FIG. 1(a) shows a structure of an optical receiver 10a for refracting signal light to an upper surface side of a semiconductor substrate 13 on a facet surface, and FIG. 1(b) shows a structure of an optical receiver 10b having a folded-back structure which reflects the signal light at the bottom surface of the semiconductor substrate 13, after refracting the signal light toward the bottom surface of the semiconductor substrate 13 at the facet surface. As shown in FIG. 1(a), the optical receiver 10a includes an optical fiber 11 which guides a signal light (shown by a broken line arrow in the drawing) to the optical receiver 10a, a planar light wave circuit 14 which converts the spot size of the signal light incident from the optical fiber 11 by using a spot size converter 12 installed inside, and guides the converted signal light to the semiconductor substrate 13, and a light-receiving element 15 installed on the semiconductor substrate 13.

When the signal light is incident on the light-receiving element 15, since the light protruding from the light-receiving element 15 is lost, it is desirable from the viewpoint of efficiency that a beam diameter of the signal light be smaller than that of the light-receiving element 15. For example, when the signal light output from the optical fiber 11 is input to the semiconductor substrate 13 as it is, the beam diameter of the signal light is excessively widened when the signal light propagates through the semiconductor substrate 13 and can be larger than that of the light-receiving element. Therefore, the optical receiver 10a requires a planar light wave circuit 14 in which the spot size converter 12 is installed. In other words, the beam waist diameter of the signal light is made wider than that of the light emitted from the optical fiber 11 by the spot size converter 12, whereby the beam spread during propagation of the semiconductor substrate 13 can be suppressed.

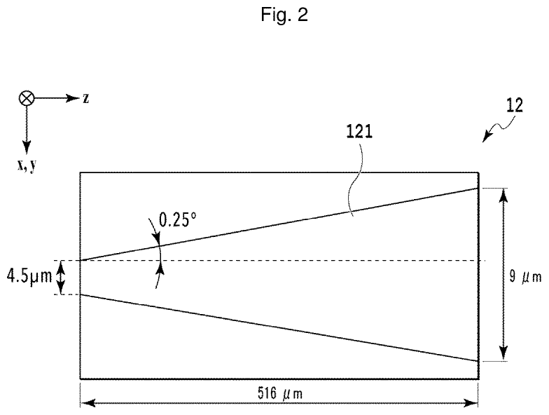

FIG. 2 is a diagram showing an example of the spot size converter 12. As shown in FIG. 2, the exemplary spot size converter 12 may be a tapered spot size converter including a waveguide 121 having a tapered shape. For example, when the core diameter at the incident position of the waveguide 121 is 4.5 μm, the core diameter at the exit position is 9 μm, and the spread angle of the waveguide 121 is 0.25°, the length of the signal light propagation direction (corresponding to a z direction in FIG. 2) of the spot size converter 12 is 516 μm. Even in consideration of the degree of freedom of design items such as the refractive index of the waveguide 121 and the required spot size, the required spot size conversion can be realized if the length of the spot size converter 12 in the z direction is 1 mm. When the spread angle of the waveguide 121 is widened to 1° or more, the loss in the waveguide becomes large, and therefore, it is necessary to set the spread angle to 1° or less. In addition, in FIG. 2, although the waveguide 121 is described as having a tapered shape extending in the traveling direction (z direction) of the signal light, it may be an inverse tapered shape as long as desired spot size conversion can be performed. Further, the surface having the spread may have a structure having a spread in either an xz plane or a yz plane or both planes in accordance with the APD shape.

Here, the connecting surface between the planar light wave circuit 14 and the semiconductor substrate 13 is not perpendicular or parallel to the traveling direction of the signal light (z direction in FIG. 1) as shown in FIG. 1(a), but a facet surface having an inclination. An angle 16a formed by a substrate surface on which the light-receiving element 15 of the semiconductor substrate 13 is mounted and the connecting surface is the same as an angle 16b formed by a bottom surface of the planar light wave circuit 14 and the connecting surface. The angles 16a and 16b may be an acute angle or an obtuse angle unless it is 90° (vertical). In the optical receiver 10a having such a configuration, the signal light whose spot size is converted by the spot size converter 12 is refracted on the facet surface, propagates in the semiconductor substrate 13, and is input obliquely to the light-receiving element 15. The signal light input into the light-absorbing layer of the light-receiving element 15 is folded back in the light-receiving element 15 by a reflection layer (not shown) formed on the upper surface of the light-receiving element 15, as in the related art.

In this way, in the optical receiver 10a according to the present disclosure, the signal light is refracted on the facet surface and made incident obliquely to the light-receiving element 15. Therefore, the optical path length in the light-absorbing layer of the light-receiving element 15 is extended, and accordingly, the external quantum efficiency is improved, and the sensitivity is enhanced.

FIG. 1(b) shows another example of the optical receiver according to the present disclosure. The optical receiver 10b shown in FIG. 1(b) further includes a reflection film 17 for totally reflecting the signal light on the bottom surface of the semiconductor substrate 13, and has such a folded-back structure in which the optical signal propagating in the semiconductor substrate 13 is reflected by the reflection film 17.

Since the optical receiver 10a has a structure in which the signal light is not folded back at the bottom surface, the distance from the spot size converter 12 to the light-receiving element 15 is relatively short. Therefore, the beam diameter in the light-receiving element 15 can be reduced, and optical design is facilitated. On the other hand, when setting the angles 16a and 16b to obtuse angles like the optical receiver 10b, when forming the facet surface on the semiconductor substrate 13 side, since an antireflection film to be described later can be formed from the upper surface side of the substrate, the mounting process is relatively simplified (however, in this case, since the signal light is refracted to the bottom surface side of the semiconductor substrate 13, it is necessary to form a folded-back structure). The structures of the optical receivers 10a and 10b are preferably selected according to the purpose and use.

A method of manufacturing optical receivers 10a and 10b according to the first embodiment of the present disclosure is described below. The method of manufacturing the optical receivers 10a and 10b includes the steps of: forming a light-receiving element 15 on the upper surface of the semiconductor substrate 13, and then protecting parts other than a part in which the facet surface is formed with a nitride film or the like; forming the facet surface by etching; forming an antireflection film on the facet surface on the semiconductor substrate 13 side and performing chip formation by cleavage; polishing an end surface to have the same angle as the facet surface on the semiconductor substrate 13 side after forming an optical path and a spot size converter 12 on the planar light wave circuit 14; forming an antireflection film on the facet surface on the planar light wave circuit 14 side, and optically connecting the antireflection film and the facet surface on the semiconductor substrate 13 side. As the above-mentioned etching, for example, wet etching can be applied. In this case, it is possible to select whether the angles 16a and 16b formed by the kind of the etchant are acute or obtuse. Further, when optically connecting the facet surfaces of the semiconductor substrate 13 side and the planar light wave circuit 14 side, matching oil or adhesive may be applied between the facet surfaces, if necessary.

The above-described manufacturing method is configured by a technique already put into practical use as a manufacturing method of an optical component including an optical receiver and an optical module. That is, since the manufacturing method of the optical receivers 10a and 10b does not require a special process and the conventional technique can be applied as it is, it is possible to manufacture the semiconductor device by a simple process.

As an alternative manufacturing method, when oblique incidence is performed without providing the facet surface on the light-receiving element 15, it is also conceivable to directly attach the light-receiving element 15 to the obliquely polished planar light wave circuit 14 or the spot size converter 12. However, in this case, it is necessary to perform an optical alignment in a state where a current is made to flow through the oblique light-receiving element 15, while holding the light-receiving element 15 at a position other than the rear surface such as the chip end, and accordingly, there is a problem of difficulty in mounting. That is, since the optical receivers 10a and 10b according to the first embodiment of the present disclosure are formed so that the facet surfaces are formed in the semiconductor substrate 13, the mounting is simplified, and it is advantageous for practical use.

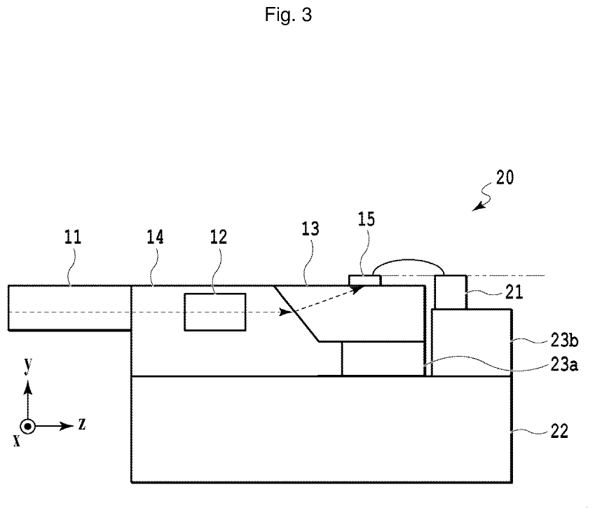

FIG. 3 is a diagram conceptually showing an example of implementation of the optical receiver according to the present disclosure. In FIG. 3, the optical receiver is depicted as having the same structure as that shown in FIG. 1(a), but it is not limited to this, and may have a folded-back structure as shown in FIG. 1(b). As shown in FIG. 3, when the optical receivers 10a and 10b according to the present disclosure are connected to a post-stage electronic member 21, if necessary, by providing spacers 23a and 23b between the semiconductor substrate 13 and the electronic member substrate 22, and between the post-stage electronic member 21 and the electronic member substrate 22, the light-receiving element 15 and the post-stage electronic member 21 can be installed on the same plane. When the light-receiving element 15 and the post-stage electronic member 21 are installed on the same plane in this way, the mounting is simplified and the high-frequency characteristics are improved by reducing the wiring length.

In the connection between the planar light wave circuit 14 and the electronic member substrate 22, a method of applying a height-adjustable adhesive to the bottom surface of the planar light wave circuit 14 and solidifying the adhesive after the optical alignment, or a method of selecting the spacer 23a after measuring the thickness of the planar light wave circuit 14 in advance can be applied. When using such a method, after the height adjustment is performed without optical alignment, facet surfaces are made to abut each other, and optical alignment can be performed only in the x-axis direction. As described above, in this case, the positioning in the z-axis direction and the y-axis direction is not required, and the mounting can be simplified.

In addition, in the optical receivers 10a and 10b, the distance between the optical fiber 11 and the post-stage electronic member 21 can be adjusted by the length in the optical axis direction of the planar light wave circuit. Therefore, the optical receiver can also flexibly cope with the size adjustment of the optical receiver.

As described above, the optical receivers 10a and 10b according to the present embodiment can realize a compact optical receiver, while realizing high sensitivity by extending the optical path length in the light-receiving element 15. Further, the mounting in the optical axis direction can be simplified as compared to a case of using a lens system which is a conventional technique.

### Second Embodiment

A second embodiment of the present disclosure will be described in detail below with reference to the accompanying drawings. An optical receiver according to the present embodiment relates to a configuration in which signal light refracted by the facet surface propagates through the substrate and obliquely enters the light-receiving element, as in the first embodiment. However, the substrate and the planar light wave circuit are different from those of the first embodiment in that the entire thickness of the substrate and the planar light wave circuit have a partially vertical bonding surface instead of a facet surface.

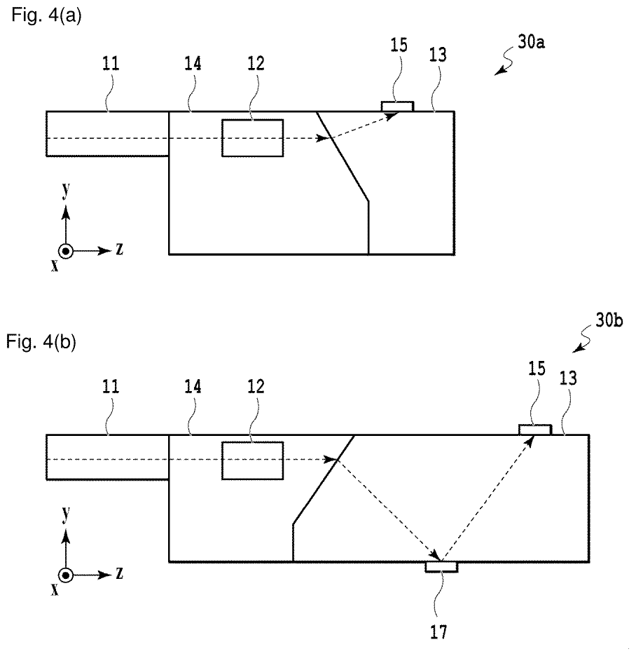

FIG. 4 is a diagram conceptually showing the structure of the optical receiver according to the second embodiment of the present disclosure, FIG. 4(a) shows an optical receiver 30a which refracts signal light to the upper surface side of the semiconductor substrate 13 on the facet surface, and FIG. 4(b) shows an optical receiver 30b having a folded-back structure which reflects the signal light to the bottom surface of the semiconductor substrate 13 after refracting the signal light to the bottom surface of the semiconductor substrate 13 on the facet surface, respectively. As shown in FIG. 4, the optical receivers 30a and 30b according to the present embodiment are configured such that, in the optical receivers 10a and 10b described above, a part of a connecting surface between the semiconductor substrate 13 and the planar light wave circuit 14 further includes a surface perpendicular to the z-direction. When the signal light is input to the semiconductor substrate 13, the signal light passes through the facet surface.

The method of manufacturing the optical receivers 30a and 30b is the same as the method described in the first embodiment, the etching process is wet etching, the bonding surface can be formed to include both a facet surface and a surface perpendicular to the facet surface, by selection of etching. Alternatively, as in the first embodiment, a two-stage process may be adopted in which the entire thickness of the substrate and the planar light wave circuit is set to be a facet surface, and then a vertical surface is formed partially by using another etchant.

Since the optical receivers 30a and 30b can be aligned by abutting on the xy plane, the alignment of the z-axis and the y-axis can be completed only by abutting on the xy plane. Therefore, there is no need for separate alignment in the y-axis and z-axis directions, and mounting can be performed only by alignment in the x-axis direction. In addition, there is an advantage that the mounting in the optical axis direction is more simplified than the lens system of the related art.

### Third Embodiment

A third embodiment of the present disclosure will be described in detail below with reference to the accompanying drawings. The optical receiver according to the present embodiment further includes an optical demultiplexer for demultiplexing signal light emitted from an optical fiber.

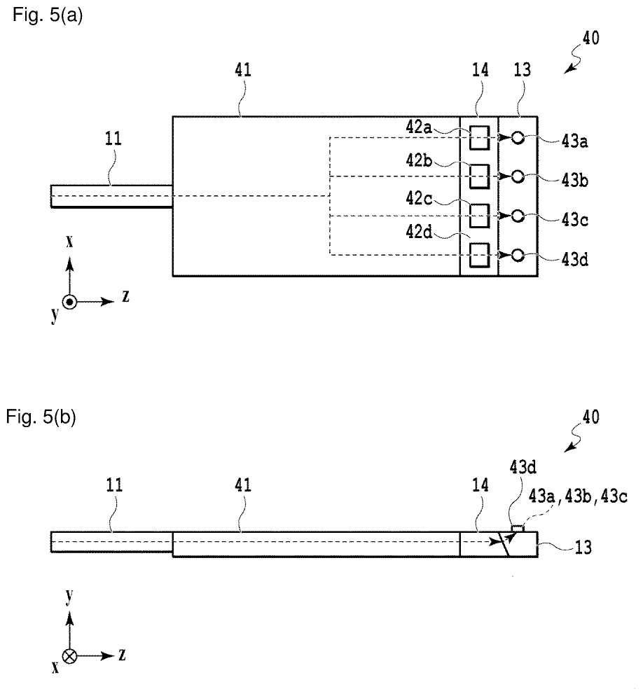

FIG. 5 is a diagram conceptually showing a structure of an optical receiver 40 according to a third embodiment of the present disclosure, FIG. 5(a) shows a top view, and FIG. 5(b) shows a side view, respectively. As shown in FIG. 5, the optical receiver 40 according to the present embodiment further includes an optical demultiplexer 41 installed between the optical fiber 11 and a spot size converters 42a-d in the optical receiver 10a described above, and has a structure in which the spot size converter 12 is replaced with four spot size converters 42a-d, and the light-receiving element 15 is replaced with four light-receiving elements 43a-d, respectively. In FIG. 5, as an example, the optical receiver 40 is depicted as a configuration in which the optical demultiplexer 41 is added to the optical receiver 10a, but a configuration in which the optical demultiplexer 41 is added to the optical receiver 10b or 30a and 30b may be adopted. In FIG. 5, the optical demultiplexer 41 is depicted to be configured independently of the planar light wave circuit 14, but it may be configured to be built in the input side of the planar light wave circuit 14.

In the optical receiver 40 having such a configuration, the signal light emitted from the optical fiber 11 is demultiplexed into a plurality of signal light beams by an optical demultiplexer, and then the spot size is converted by the spot size converter 12 and made incident on a plurality of light-receiving elements 43a-d via the facet surface. Although the number of light-receiving elements is four as an example in FIG. 5, the present invention is not limited thereto, and an arbitrary number of light-receiving elements may be included.

In the optical receiver 40, like the optical receivers 10a and 10b and the optical receivers 30a and 30b, it is possible to realize an optical receiver that is smaller and compatible with multiplexing systems, while achieving high sensitivity, by the oblique incidence of the signal light on the light-receiving element 15 and the extension of the optical path length due to folding-back on the upper surface of the light receiving element 15. Also in mounting, as in the optical receivers 10a and 10b and the optical receivers 30a and 30b, mounting in the optical axis direction becomes easier than in the conventional lens system, by butting of the semiconductor substrate 13 and the planar light wave circuit 14. Further, by expanding the beam waist of the signal light by the spot size converter 12 and making the signal light incident on the light-receiving element 15, an optical receiver having higher power resistance than that of a waveguide type photodiode known as a conventional technique can be realized.

### Fourth Embodiment

Hereinafter, a fourth embodiment of the present disclosure will be described in detail with reference to the drawings. An optical receiver according to the present embodiment relates to a configuration in which signal light is directly reflected on the bottom surface of the substrate in a configuration having a folded-back structure such as an optical receiver 10b and an optical receiver 30b.

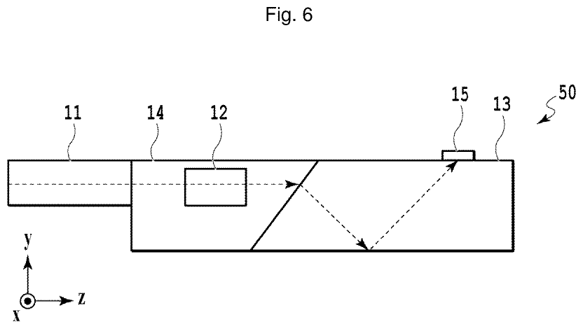

FIG. 6 is a diagram conceptually showing the structure of the optical receiver 50 according to the fifth embodiment of the present invention. As shown in FIG. 6, the optical receiver 50 has a configuration not including the reflection film 17 in the configuration of the optical receiver 10b. However, in the optical receiver 50, the refractive index of a material (for example, a spacer 22a in FIG. 3) that is in contact with the bottom surface of the semiconductor substrate 13 satisfies the expression (1).

$$[ Math . 1 ]$$

$${n}_{c} \leq n sin ( {θ}_{x} + {θ}_{b} ) \qquad ( Expression 1 )$$

Here, n_{c} is a refractive index of a material that is in contact with the bottom surface of the semiconductor substrate 13, n is a refractive index of the semiconductor substrate 13, θₓ is an angle formed by the bottom surface of the semiconductor substrate 13 and a facet surface, and θ_{b} is an angle formed by the traveling direction of the incident signal light from the planar light wave circuit 14 to the semiconductor substrate 13 and a perpendicular line of the facet surface.

When the condition of the expression (1) is satisfied, since the total reflection of the signal light is generated on the bottom surface of the substrate, a folded-back structure is realized similarly to the optical receiver 10b. As a result, since the signal light is obliquely incident on the light-receiving element 15, the optical path length of the light-receiving element 15 is extended, and the high sensitivity of the element is realized. In addition, the optical receiver 50 according to the present embodiment does not require the reflection film 17, and therefore, can be made smaller in size.

The optical receiver 50 having such a configuration can be manufactured by a manufacturing method similar to the optical receiver (e.g., the optical receiver 10b) according to the present disclosure. In the manufacturing of the optical receiver 50, it is necessary to control the angle of the facet surface with high accuracy, but this can be easily realized, for example, by processing using a dicing blade or the like having a V-shaped tip. That is, the optical receiver 50 can be manufactured by a simple process.

### INDUSTRIAL APPLICABILITY

As described above, the optical receiver according to the present disclosure has a structure having a facet surface, whereby the optical path length in the light-receiving element is extended, and accordingly, the optical receiver having higher sensitivity and smaller size than the related art can be realized. Such an optical receiver is expected to be applied particularly as a high-speed optical communication apparatus.

1. An optical receiver comprising:
a planar light wave circuit which includes a spot size converter for converting a spot size of signal light incident from an optical fiber;
a semiconductor substrate connected to the planar light wave circuit via a connecting surface; and
a light-receiving element mounted on a substrate surface of the semiconductor substrate,
wherein the connecting surface is a facet surface that is in contact with the substrate surface at an acute angle or an obtuse angle so that the signal light emitted from the spot size converter is incident on a light-receiving surface of the full light-receiving element.

2. The optical receiver according to claim 1,
wherein the connecting surface further comprises a surface that is in contact with the facet surface and perpendicular to a traveling direction of the signal light.

3. The optical receiver according to claim 1- or 2,
wherein the semiconductor substrate further comprises a folded-back structure that reflects the signal light having passed through the facet surface at a bottom surface.

4. The optical receiver according to claim 3,
wherein the semiconductor substrate further comprises a reflective film on a bottom surface thereof, the reflective film being configured to totally reflect the signal light.

5. The optical receiver according to claim 3,
wherein a refractive index of a material that is in contact with the bottom surface of the semiconductor substrate satisfies the following expression 1.
$$[ Math . 1 ]$$
$${n}_{c} \leq n sin ( {θ}_{x} + {θ}_{b} ) \qquad ( Expression 1 )$$

6. The optical receiver according to claim 1, further comprising:
an optical demultiplexer installed between the optical fiber and the spot size converter,
wherein there are multiple numbers of the spot size converter and the light-receiving element.

7. The optical receiver according to claim 2,
wherein the semiconductor substrate further comprises a folded-back structure that reflects the signal light having passed through the facet surface at a bottom surface.
